(19) United States
(12) Patent Application Publication
(10) Pub. No.: US 2020/0203450 A1
(43) Pub. Date: Jun. 25, 2020

(54) DISPLAY STRUCTURE AND MANUFACTURING METHOD THEREOF, AND DISPLAY DEVICE

(71) Applicant: Yungu (Gu'an) Technology Co., Ltd., Langfang (CN)

(72) Inventors: Junhui LOU, Kunshan (CN); Lu ZHANG, Kunshan (CN); Yanqin SONG, Kunshan (CN)

(73) Assignee: Yungu (Gu'an) Technology Co., Ltd., Langfang (CN)

(21) Appl. No.: 16/808,817

(22) Filed: Mar. 4, 2020

Related U.S. Application Data
(63) Continuation of application No. PCT/CN2019/072747, filed on Jan. 23, 2019.

(30) Foreign Application Priority Data
Aug. 15, 2018 (CN) 201810929834.9

(51) Int. Cl. H01L 27/32

(52) U.S. Cl. CPC H01L 27/3246; H01L 2227/323; H01L 27/326

(57) ABSTRACT

The present disclosure provides a display structure and a display device. The display structure includes: a first region, including a plurality of first pixels; a second region, including a plurality of second pixels, a resolution of the second region is lower than that of the first region; and a pixel defining layer. A portion of the pixel defining layer which is corresponding to the first region is provided with a plurality of first openings, and the plurality of first openings are corresponding to the plurality of first pixels; a portion of the pixel defining layer which is corresponding to the second region is provided with a plurality of second openings, and the plurality of second openings are corresponding to the plurality of second pixels. Areas of the plurality of first openings are less than those of the plurality of second openings.

### CROSS REFERENCE TO RELATED APPLICATIONS

This disclosure is a Bypass Continuation Application of International Patent Application No. PCT/CN2019/072747, filed on Jan. 23, 2019, which claims priority to Chinese Patent Application No. 2018109298349, titled “DISPLAY PANEL AND DISPLAY DEVICE”, filed on Aug. 15, 2018, the contents of all of which are incorporated herein by reference.

### TECHNICAL FIELD

The present disclosure relates to a display structure and a manufacturing method thereof, and a display device.

### BACKGROUND

Organic light emitting diode (OLED) elements are light emitting elements. A display panel can be made into an OLED display panel by using OLED elements.

Generally, different regions of the OLED display panel have the same resolution. With the wide application of OLED display panels, designing OLED display panels with different resolutions in different regions is a problem to be solved.

### SUMMARY

The present disclosure provides a display structure and a manufacturing method thereof, and a display device.

According to a first aspect of examples of the present disclosure, there is provided a display structure, including: a first region, includes a plurality of first pixels; a second region, includes a plurality of second pixels, where a resolution of the second region is lower than that of the first region; and a pixel defining layer, where a portion of the pixel defining layer which is corresponding to the first region is provided with a plurality of first openings, and the plurality of first openings are corresponding to the plurality of first pixels; a portion of the pixel defining layer which is corresponding to the second region is provided with a plurality of second openings, and the plurality of second openings are corresponding to the plurality of second pixels; where areas of the plurality of first openings are less than those of the plurality of second openings.

According to the display structure of the present disclosure, by making the areas of the first openings less than those of the second openings, the display structure can have different pixels per inch (referred briefly to as PPI) in different regions, thereby meeting different application requirements. So, the region with low PPI can have higher transparency and the light diffraction thereof is reduced, and the region with high PPI can guarantee the display effect.

Optionally, the plurality of first openings have substantially the same areas and shapes, and the plurality of second openings have substantially the same areas and shapes; outer margins of at least two adjacent first openings of the plurality of first openings are respectively connected to form an imaginary opening that has substantially the same area and shape as each of the plurality of second openings.

In this case, the imaginary opening having the same area and shape as the second opening is divided into a plurality of first openings via the pixel defining layer, which enables one display region of the display structure to have different PPI through the simple structure. And the number of the first openings, into which the imaginary opening is divided, can be selected according to the requirements, thereby selecting the required PPI, which enhances the flexibility of the display structure.

Optionally, the plurality of first pixels are same as the plurality of first openings in number, and positions of the plurality of first pixels are corresponding to positions of the plurality of first openings; the plurality of second pixels are same as the plurality of second openings in number, and positions of the plurality of second pixels are corresponding to positions of the plurality of second openings; the first pixels in the imaginary opening have the same color, and are different from ones of the plurality of first pixels which are in another adjacent imaginary opening in color; adjacent ones of the plurality of second pixels have different colors.

In this case, it can meet the requirements of pixel arrangement while making the display structure to have different PPI in different regions, thereby achieving the color display with high PPI.

In this case, the first openings and the second openings can be formed in the region with different PPI via the mask having apertures with the same areas, shapes or arrangement, thereby preventing the mask from being deformed due to the non-uniform force in the stretching process.

Optionally, at least three of the plurality of first pixels form a first pixel unit, the at least three first pixels of the first pixel unit have different colors; at least three of the plurality of second pixels form a second pixel unit, the at least three second pixels of the second pixel unit have different colors.

Optionally, each of the plurality of first pixels comprises one of a red pixel, a green pixel or a blue pixel, and each of the plurality of second pixels comprises one of a red pixel, a green pixel or a blue pixel.

Optionally, shapes of the plurality of first openings and the plurality of second openings comprise a polygon shape or circle shape.

Optionally, the polygon shape comprises one of a triangle, a quadrangle, and a hexagon.

In this case, both the first opening and the second opening of different shapes can form pixels of different shapes, so as to meet different usage requirements.

Optionally, an area of the first region is greater than that of the second region.

Optionally, a middle region of an edge portion on a side of the first region is provided with a notch, and the second region is located in the notch.

According to a second aspect of the present disclosure, there is provided a manufacturing method of a display structure, including: providing a substrate divided into a first region and a second region; forming a pixel defining layer on the substrate, forming a plurality of first openings in a portion of the pixel defining layer which is corresponding to the first region, and forming a plurality of second openings in a portion of the pixel defining layer which is corresponding to the second region, where areas of the plurality of first openings are less than areas of the plurality of second openings.

Optionally, before forming the pixel defining layer on the substrate, the method further includes: forming a first lower electrode layer in the first region, the first lower electrode layer includes a plurality of first lower electrodes corresponding to the plurality of first openings which are to be formed; forming a second lower electrode layer in the second region, the second lower electrode layer includes a plurality of second lower electrodes corresponding to the plurality of second openings which are to be formed.

Optionally, the method further includes: forming a first light emitting layer on each of the plurality of first lower electrodes and in a corresponding one of the plurality of first openings, and forming a second light emitting layer on each of the plurality of second lower electrodes and in a corresponding one of the plurality of second openings; forming a upper electrode layer on the first light emitting layer and the second light emitting layer.

Optionally, the first light emitting layer and the second light emitting layer are formed by a mask that has apertures with the same dimension.

Examples of the disclosure further provide a display device. The display device includes any one of the above display structures. The display device further includes a camera element and a sensing element located at a region corresponding to and below the second region.

### BRIEF DESCRIPTION OF THE DRAWINGS

The accompanying drawings, which are incorporated in and constitute a part of the present description, illustrate examples consistent with the present disclosure and serve to explain the principles of the present disclosure together with the description.

FIG. 1 is a plan view of an organic light emitting diode display structure according to an example of the present disclosure;

FIG. 2 is a cross-sectional view taken along line A-A in FIG. 1;

FIG. 3 is a partial cross-sectional view of the organic light emitting diode display structure according to an example of the present disclosure;

FIG. 4 is another plan view of an organic light emitting diode display structure according to an example of the present disclosure, with different pixel units arrangement from that of the organic light emitting diode display structure of FIG. 1;

FIG. 5 is a schematic diagram of forming a first light emitting layer and a second light emitting layer on a substrate by using a fine metal mask according to an example of the present disclosure;

FIG. 6 is yet another plan view of an organic light emitting diode display structure according to an example of the present disclosure, with different pixel units arrangement from that of the organic light emitting diode display structure of FIG. 1;

FIG. 7 is still another plan view of an organic light emitting diode display structure according to an example of the present disclosure, with different pixel units arrangement from that of the organic light emitting diode display structure of FIG. 1;

FIG. 8 is still another plan view of an organic light emitting diode display structure according to an example of the present disclosure, with different pixel units arrangement from that of the organic light emitting diode display structure of FIG. 1;

FIG. 9 is a schematic flowchart of a method of manufacturing a display structure according to an example of the present disclosure;

FIG. 10 is another schematic flowchart of a method of manufacturing a display structure according to an example of the present disclosure; and

FIG. 11 is a schematic diagram of a plan structure of a display device according to an example of the present disclosure.

### DETAILED DESCRIPTION OF THE EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

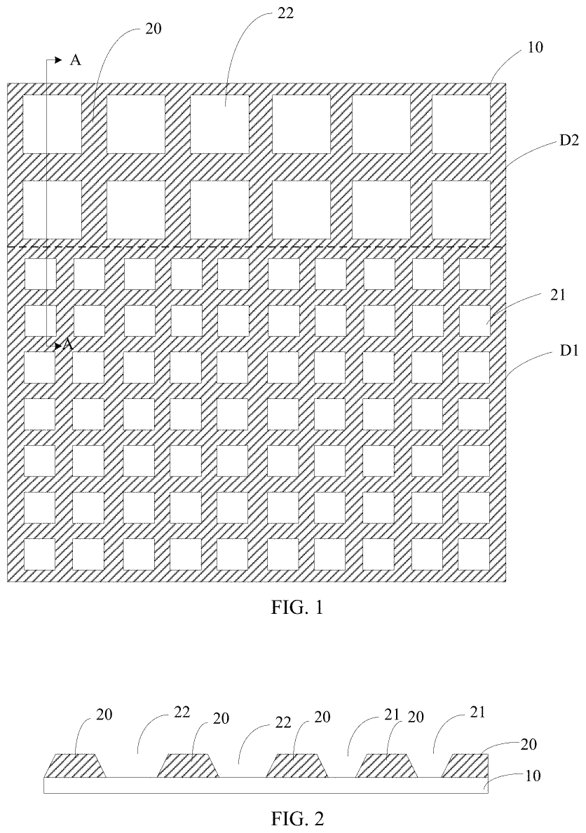

Examples of the present disclosure provide a display structure. FIG. 1 is a plan view of a display structure according to an example of the present disclosure. FIG. 2 is a cross-sectional view taken along line A-A in FIG. 1.

As shown in FIG. 1 and FIG. 2, the display structure includes: a first region D1 that includes a plurality of first pixels; a second region D2 that includes a plurality of second pixels, the second region has a lower resolution than that of the first region Dl; and a pixel defining layer 20. A portion of the pixel defining layer 20 which is corresponding to the first region D1 is provided with a plurality of first openings 21, and the plurality of first openings correspond to the plurality of first pixels, respectively. A portion of the pixel defining layer 20 which is corresponding to the second region D2 is provided with a plurality of second openings 22, and the plurality of second openings correspond to the plurality of second pixels. The first opening 21 has a smaller area than that of the second opening 22. In examples, first openings 21 have substantially the same areas and shapes, and second openings 22 have substantially the same areas and shapes. Outer margins of adjacent first openings are connected to form an imaginary opening that has substantially the same area and shape as a corresponding second opening 22.

The pixel defining layer 20 is formed on the substrate 10. The substrate 10 may be a rigid substrate or a flexible substrate. The rigid substrate may be made of, for example, glass, and the flexible substrate may be made of, for example, polyimide, polycarbonate, polyethylene terephthalate, or the like. The flexible substrates can be suitable for manufacturing flexible display panels.

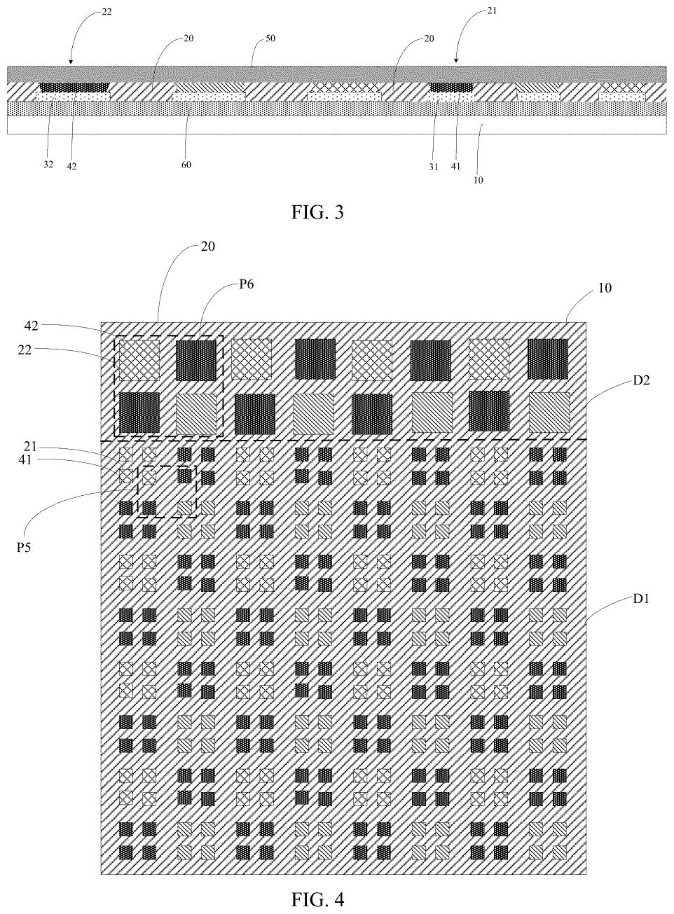

An array layer 60 (shown in FIG. 3) may be formed between the substrate 10 and the pixel defining layer 20, and a plurality of thin film transistors are formed in the array layer. A thin film transistor is respectively disposed below the first openings 21 and the second openings 22.

The pixel defining layer 20 is configured to define regions where pixels are located. Pixels in OLED are formed by first openings 21 and second openings 22 surrounded or defined by the pixel defining layer 20.

The OLED may include a lower electrode (for example, an anode) layer, a light emitting layer, an upper electrode (for example, a cathode) layer, and the like. In addition, the OLED may further include one or a combination of a hole injection layer, a hole transport layer, an electron blocking layer, a hole blocking layer, an electron transport layer, and an electron injection layer.

The first region D1 is provided to be a region of high pixel density, and the second region D2 is provided to be a region of low pixel density. The first openings 21 in the first region D1 have smaller areas than those of the second openings 22 in the second region D2, so that the first region D1 has a different PPI from that of the second region D2. Therefore, a new type of OLED display structure is formed to meet different application requirements.

FIG. 3 is a partial cross-sectional view of a display structure according to an example of the present disclosure. As shown in FIG. 3, a first lower electrode 31 and a first light emitting layer 41 are formed at locations corresponding to the respective first openings 21. The first light emitting layer 41 is located over the corresponding first lower electrode 31 and fills the corresponding first opening 21. A second lower electrode 32 and a second light emitting layer 42 are formed at locations corresponding to the respective second openings 22. The second light emitting layer 42 is located over the corresponding second lower electrode 32 and fills the corresponding second opening 22. The first light emitting layers 41 and the second light emitting layers 42 are covered with an upper electrode layer 50.

When the light emitting layer is formed via the evaporation process, a mask such as a fine metal mask is applied. The fine metal mask has a plurality of apertures. Vaporized material, which is evaporated, is deposited on the substrate through the apertures, thereby forming the light emitting layer.

Light emitting layers which emit light of the same color can be evaporated and thus formed simultaneously. When light emitting layers which emit light of a certain color are evaporated, the fine metal mask is aligned with the substrate 10. Apertures of the fine metal mask are corresponding to openings of the pixel defining layer in which light emitting layers capable of emitting light of this color are to be formed. Vaporized organic material, which is evaporated, can be deposited in the openings of the pixel defining layer through the apertures. In order to deposit the light emitting layers with a uniform thickness in the openings, the apertures of the fine metal mask usually have sizes larger than those of the openings of the pixel defining layer.

FIG. 4 is a plan view of a display structure according to an example of the present disclosure. As shown in FIG. 4, the first region D1 has the plurality of first openings 21, and the second region D2 has the plurality of second openings 22. Each of the first openings 21 is formed with a first pixel (corresponding to the first light emitting layer 41), and each of the second openings 22 is formed with a second pixel (corresponding to the second light emitting layer 42).

An imaginary opening is formed by connecting outer margins of adjacent first openings 21. For example, as shown in FIG. 4, an imaginary opening is formed by connecting outer margins of two first openings 21 in a third row, and two first openings 21 in a fourth row and in the same column as two first openings 21 of the third row. This imaginary opening has substantially the same area and shape as those of the second opening 22.

Although in FIG. 4, the imaginary opening is formed by four first openings 21, it is to be understood that the present disclosure is not limited thereto. For example, the imaginary opening may be formed by two first openings 21, that is, the imaginary opening having the same area and shape as those of the second opening 22 may be separated into two first openings 21 by the pixel defining layer. In this case, the number of the first openings, into which the imaginary opening is divided, can be selected according to the requirements, thereby selecting the required PPI, which enhances the flexibility of the display structure.

In order to show pixels of different colors in the drawing, squares with different filling patterns are used to represent pixels of different colors. A region where the square with filling pattern is located indicates a region where the pixel is formed. Pixels, which are formed in regions where the squares with the same filling patterns are located, have the same colors, and pixels, which are formed in regions where the squares with different filling patterns are located, have different colors.

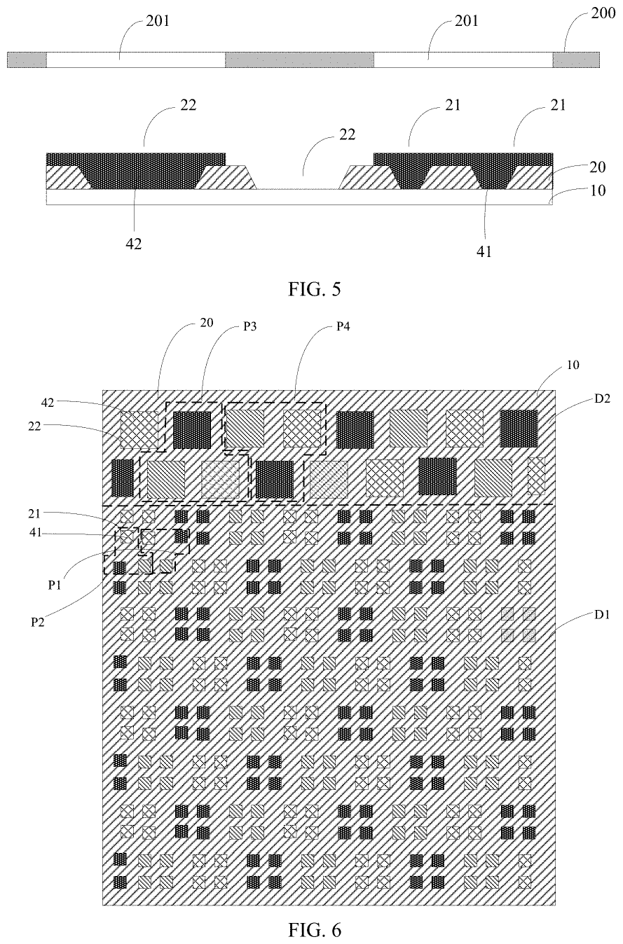

As shown in FIG. 5, the first light emitting layer 41 and the second light emitting layer 42 may be formed by using the fine metal mask 200. In order to ensure accuracy of the evaporation and avoid deformation caused by the non-uniform force during the process of stretching the fine metal mask, the fine metal mask 200 may has apertures 201 with the same areas and shapes. In this way, the first openings and the second openings can be formed in regions with different PPI via the mask having apertures with the same areas, shapes or arrangement, thereby preventing the mask from being deformed due to the non-uniform force in the stretching process.

The fine metal mask 200 is aligned with the substrate 10, and apertures 201 of the fine metal mask 200 are corresponding to regions where the light emitting layers with this color is to be formed. For example, the fine metal mask 200 is aligned with the substrate 10, and the apertures 201 of the fine metal mask 200 are corresponding to openings in the above regions where the light emitting layers with the same colors are to be formed. As shown in FIG. 5, one aperture 201 is corresponding to one second opening 22 in the second region, and another aperture 201 is corresponding to adjacent first openings 21 in the first region that combined are included in an imaginary opening.

When light emitting layers are formed by using the evaporation process, light emitting layers which emit light of the same color can be formed simultaneously. For example, first light emitting layers 41 with the same color, which are corresponding to the first openings 21 in number, may be simultaneously formed in the imaginary opening formed by connecting outer margins of adjacent first openings 21, and each of the second openings 22 may be formed with one second light emitting layer 42.

As shown in FIG. 6, for the first region D1, three first pixels 41 form a first pixel unit P1 (or P2). The three first pixels 41 are different from each other in color. For example, these three first pixels 41 are respectively a red pixel, a green pixel, and a blue pixel. The three first pixels 41 are located in two adjacent rows, for example, one of the three first pixels is in the second row of the first region D1, and other two of the three first pixels are in third rows of the first region D1, and the three first pixels 41 are adjacent to each other. In addition, the one of the three first pixels 41 is located in the middle of the other two first pixels 41, so that the three first pixels 41 form a shape as the Chinese character “ [symbol] ”, or inverted Chinese character “ [symbol] ”. By controlling one or more of the three first pixels 41 to emit light, at least two different colors can be displayed, and a full-color screen display in the first region can be realized.

Similarly, as shown in FIG. 6, for the second region D2, three second pixels 42 form a second pixel unit P3 (or P4). The three second pixels 42 are different from each other in color, for example, the three second pixels 42 are respectively a red pixel, a green pixel, and a blue pixel. The three second pixels 42 are located in two adjacent rows, for example, one of the three second pixels is in the first row of the second region D2, and other two of the three second pixels are in second rows of the second region D2, and the three second pixels 42 are adjacent to each other. In addition, the one of the three second pixels 42 is located in the middle of the other two second pixels 42, so that the three second pixels 42 form a shape as the Chinese character “ [symbol] ”, or inverted Chinese character “ [symbol] ”. The shape of Chinese character “ [symbol] ” also can be called a shape of regular triangle. By controlling one or more of the three second pixels 42 to emit light, at least two different colors can be displayed, and a full-color screen display in the second region can be realized.

Alternatively, as shown in FIG. 4, for the first region D1, four first pixels 41 form a first pixel unit P5. The four first pixels 41 are located in two adjacent rows and are adjacent to each other. For example, the four first pixels 41 are in the second row and the second column, in the second row and the third column, in the third row and the second column, and in the third row and the third column of the first region D1, respectively. Among the four first pixels 41, every two adjacent first pixels 41 are different from each other in color. For example, the first pixel 41 in the second row and the second column is a red pixel, the first pixel 41 in the second row and the third column is a green pixel, the first pixel 41 in the third row and the second column is a green pixel, and the first pixel 41 in the third row and the third column is a blue pixel. In addition, the four first pixels 41 form a first pixel unit P5 with a quadrangular shape (for example, a rectangular shape). By controlling one or more of the four first pixels 41 to emit light, at least two different colors can be displayed, and the full-color screen display in the first region can be realized.

Similarly, as shown in FIG. 4, for the second region D2, four second pixels 42 form a second pixel unit P6. The four second pixels 42 are located in two adjacent rows and are adjacent to each other. For example, the four second pixels 42 are in the first row and the first column, in the first row and the second column, in the second row and the first column, as well as in the second row and the second column in the second region D2, respectively. Among the four second pixels 42, every two adjacent second pixels 42 are different from each other in color. For example, the second pixel 42 in the first row and the first column is a red pixel, the second pixel 42 in the first row and the second column is a green pixel, the second pixel 42 in the second row and the first column is a green pixel, and the second pixel 42 in the second row and the second column is a blue pixel. In addition, the four second pixels 42 form a second pixel unit P6 with a quadrangular shape. By controlling one or more of the four second pixels 42 to emit light, at least two different colors can be displayed, and the full-color screen display in the second region can be realized.

Although the shapes of both the first openings and the second openings are quadrangular in FIG. 4, it is to be understood that the present disclosure is not limited thereto. For example, the first openings and the second openings may also be triangular. In this case, both the first openings and the second openings with different shapes may form pixels with different shapes, thereby meeting different usage requirements.

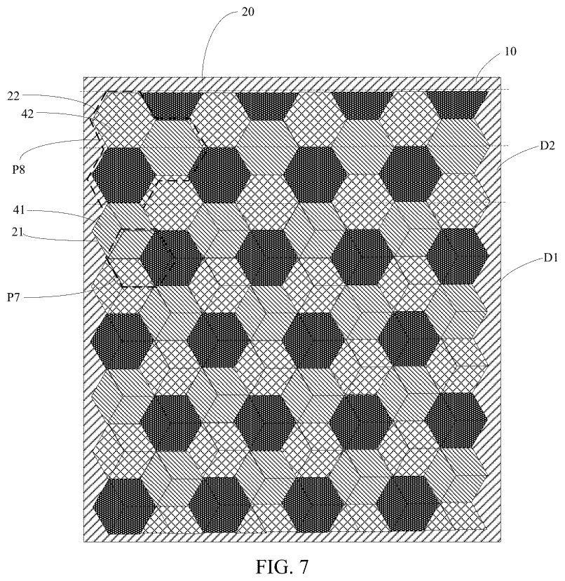

As shown in FIG. 7, for the first region D1, three first pixels 41 of different colors form a first pixel unit P7. The three first pixels 41 form the first pixel unit P7 with a regular hexagon shape. The three first pixels 41 are located in two adjacent rows and are adjacent to each other. The first light emitting layers, which are between two dotted lines in a lateral direction in FIG. 7, are arranged in one row. The three first light emitting layers are, e.g., located in two adjacent rows and adjacent to each other. The three first pixels 41 form the first pixel unit P7 having a regular hexagon shape.

For the second region D2, three second pixels 42 form a second pixel unit P8. The three second pixels 42 are different from each other in color, and are respectively a red pixel, a green pixel, and a blue pixel. The three second pixels 42 are located in two adjacent rows and adjacent to each other. The shape of each second pixel 42 is a regular hexagon shape. In a case where light emitting layers between two dotted lines in the lateral direction in FIG. 7 are arranged in one row, the three second pixels are not only adjacent to each other, but also located in two adjacent rows. The three second pixels can form the second pixel unit P8 having a dodecagon shape as shown in FIG. 7.

In order to clearly show the configuration of the display structure, the size of the configuration of the display structure is magnified. Therefore, in the above FIG. 6 and FIG. 7, some first pixels located on an edge portion of the first region and some second pixels located on the edge portion of the second region are not complete structurally. And the drawings are only illustrative. In practice, the sizes of the first pixels and the second pixels are very small, and the first pixels located on the edge portion of the first region, as well as the second pixels located on the edge portion of the second region usually have complete structures.

Optionally, the first region has an area larger than that of the second region.

The first region has a resolution greater than that of the second region. The higher the resolution, the clearer the display image, and the richer the details of the image. However, since it is necessary to form driving circuits having low light transmittance, the light diffraction effect is apparent. Therefore, the higher the resolution, the lower the light transmittance, and the more apparent the light diffraction. In contrast, the lower the resolution, the higher the light transmittance, and the less apparent the light diffraction.

For the OLED display structure, most regions of the display structure are used to display images, and a high-resolution display region needs to be configured. So, the first region with a large area is served as the region for displaying images, and the second region can meet the requirements that a small region of the display structure has a higher light transmittance. Therefore, the second region may have a smaller area. Accordingly, the area of the first region D1 is greater than that of the second region D2.

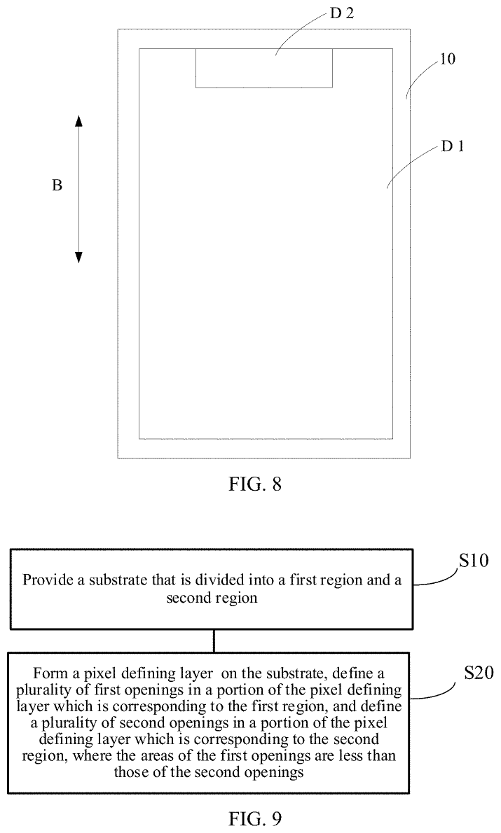

Optionally, as shown in FIG. 8, in the display structure, along a longitudinal direction (the longitudinal direction is, for example, a direction indicated by the double arrow B in the drawing) of the substrate 10, a middle region of the edge portion of the first region D1 is provided with a notch, and the second region D2 is located in the notch.

In this example, as shown in FIG. 8, along the longitudinal direction of the substrate 10, the middle position of an upper edge of the first region D1 is provided with the notch, and the second region D2 is located in the notch.

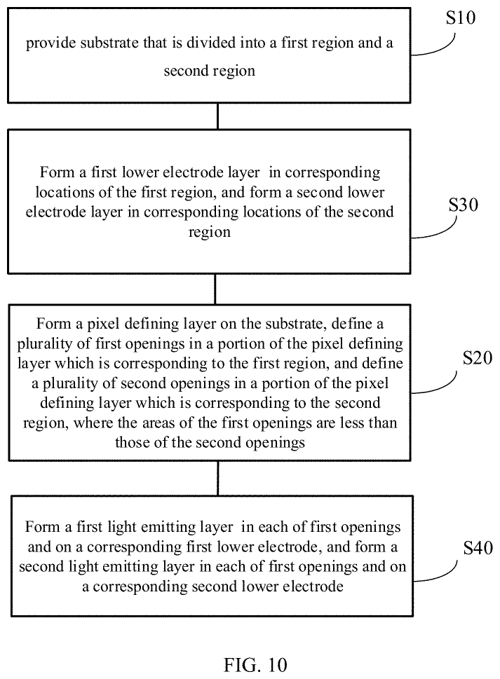

Examples of the present disclosure further provide a manufacturing method of the display structure. As shown in FIG. 9, the method includes the following steps S10 to S20.

At step S10, a substrate that is divided into a first region and a second region is provided.

At step S20, a pixel defining layer is formed on the substrate, a plurality of first openings are defined in a portion of the pixel defining layer which is corresponding to the first region, and a plurality of second openings are defined in a portion of the pixel defining layer which is corresponding to the second region, where the areas of the first openings 21 are less than those of the second openings 22.

By using the manufacturing method in this example, the display structures of the above examples can be manufactured. The pixel defining layer can be made of an organic material, and the substrate is entirely covered with the pixel defining layer. Specifically, an organic material layer may be formed on the substrate first, and then the organic material layer may be patterned to remove portions of the organic material layer which are corresponding to the first openings and the second openings, while retaining the other portions of the organic material layer. The remaining organic material layer forms a pixel defining layer 20, so that first openings in the first region have smaller areas than those of second openings in the second region.

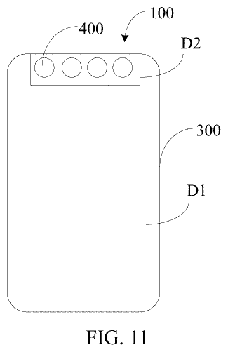

Optionally, as shown in FIG. 10, before the pixel defining layer is formed on the substrate, the method further includes step S30. At step S30, a first lower electrode layer is formed in corresponding locations of the first region D1, and a second lower electrode layer is formed in corresponding locations of the second region D2.

The first lower electrode layer includes first lower electrodes that are located at regions corresponding to the first openings of the pixel defining layer which is to be formed, and the second lower electrode layer includes second lower electrodes that are located at regions corresponding to the second openings of the pixel defining layer which is to be formed.

Optionally, as shown in FIG. 10, after the pixel defining layer 20 is formed, the method further includes step S40. At step S40, a first light emitting layer 41 is formed in each of first openings 21 and on a corresponding first lower electrode 31, and a second light emitting layer 42 is formed in each of first openings 22 and on a corresponding second lower electrode 32.

The first light emitting layer 41 is formed over the first lower electrode 31 and fills the first opening 21. And the second light emitting layer 42 is formed over the second lower electrode 32 and fills the second opening 22.

Optionally, an upper electrode layer 50 is formed on the first light emitting layers 41 and the second light emitting layers 42.

In the above example, the first lower electrodes and the second lower electrodes are formed before the pixel defining layer is formed. Specifically, the substrate may be entirely covered with a conductive material layer, and then the conductive material layer is patterned, so as to retain parts of the conductive material layer which are located at the first openings and the second openings, and to remove other parts of the conductive material layer. Accordingly, the remaining conductive material layer is the first lower electrodes located at regions where the first openings are, and the second lower electrodes located at regions where the second openings are.

In the above examples, after the pixel defining layer is formed, by means of evaporation or printing, the first light emitting layer may be formed in the first openings and the second light emitting layer may be formed in the second openings. And then a conductive material layer is formed on first light emitting layers and second light emitting layers, and the conductive material layer is served as the upper electrode layer.

Optionally, that the first light emitting layer is formed in the first opening and on the corresponding first lower electrode, and the second light emitting layer is formed in the second opening and on the corresponding second lower electrode, further includes: a first organic material layer is formed in the first opening, and a second organic material layer is formed in the second opening.

In this example, the first organic material layer and the second organic layer are formed via the evaporation process, which can be performed by using the fine metal mask having apertures with the same dimension.

The above display structure may further include other structures, for example, the array layer 60 shown in FIG. 3 and the like. The array layer 60 is a layer configured to control the light emission of the OLED elements, and includes, for example, a gate layer, a gate insulation layer, an active layer, a source/drain layer, a planarization layer, and the like.

The process for forming the pixel defining layer, the lower electrode layer, the upper electrode layer, the array layer, and the light emitting layer can be implemented by using existing processes. For example, the aforementioned patterning process is, for example, a photolithography process or a printing process. The photolithography process includes, for example, coating, exposing, developing, etching, and/or stripping the photoresist. The specific process is not described herein again.

Examples of the present disclosure further provide a display device, including the display structure described in any one of the above examples.

Optionally, as shown in FIG. 11, the display device 100 includes a display structure 300 and a camera 400. The camera 400 is disposed below the second region of the display structure 300.

In this example, although taking the camera 400 as an example to describe the elements located below the screen and in the region corresponding to the second region, the present disclosure is not limited thereto. In addition to the camera 400, the present disclosure can also include sensing elements 500, such as light sensing elements and the like.

Common cameras can usually capture images from two different directions. For example, one of the two directions is towards the rear of the mobile terminal, and the other one of the two directions is towards the front of the mobile terminal, i.e., taking a selfie. When taking a selfie through the camera of the mobile terminal, the camera needs to use the light, which is transmitted through the display panel, to capture images, and thus the camera is disposed at a position corresponding to the second region. Due to the low resolution of the second region, the light transmittance is higher and the light diffraction effect is smaller, which facilitates the improvement of the sharpness of the image captured by the camera. In addition, the second area can also display images. The display region corresponding to the first region may be served as a region configured to display main images. In this way, the displaying region of the display device can be increased, and a full-screen display of the display device can be realized.

The display device described above may be any product or component with display function, such as an electronic paper, a mobile phone, a tablet computer, a television, a monitor, a notebook computer, a digital photo frame, a navigator, a wearable device, and the like.

Some other embodiments of the present disclosure can be available to those skilled in the art upon consideration of the specification and practice of the various embodiments disclosed herein. The present application is intended to cover any variations, uses, or adaptations of the present disclosure following general principles of the present disclosure and include the common general knowledge or conventional technical means in the art without departing from the present disclosure. The specification and examples can be shown as illustrative only, and the true scope and spirit of the disclosure are indicated by the following claims.

1. A display structure, comprising:
a first region, comprising a plurality of first pixels;
a second region, comprising a plurality of second pixels, a resolution of the second region being lower than that of the first region; and
a pixel defining layer, wherein a portion of the pixel defining layer which is corresponding to the first region is provided with a plurality of first openings, and the plurality of first openings are corresponding to the plurality of first pixels; a portion of the pixel defining layer which is corresponding to the second region is provided with a plurality of second openings, and the plurality of second openings are corresponding to the plurality of second pixels;
wherein areas of the plurality of first openings are less than those of the plurality of second openings.

2. The display structure according to claim 1, wherein the plurality of first openings have substantially the same areas and shapes, and the plurality of second openings have substantially the same areas and shapes;
outer margins of at least two adjacent first openings of the plurality of first openings are respectively connected to form an imaginary opening that has substantially the same area and shape as each of the plurality of second openings.

3. The display structure according to claim 2, wherein the plurality of first pixels are same as the plurality of first openings in number, and positions of the plurality of first pixels are corresponding to positions of the plurality of first openings;
the plurality of second pixels are same as the plurality of second openings in number, and positions of the plurality of second pixels are corresponding to positions of the plurality of second openings;
the first pixels in the imaginary opening have the same color, and are different from ones of the plurality of first pixels which are in another adjacent imaginary opening in color;
adjacent ones of the plurality of second pixels have different colors.

4. The display structure according to claim 3, wherein at least three of the plurality of first pixels form a first pixel unit, the at least three first pixels of the first pixel unit have different colors; at least three of the plurality of second pixels form a second pixel unit, the at least three second pixels of the second pixel unit have different colors.

5. The display structure according to claim 3, wherein each of the plurality of first pixels comprises one of a red pixel, a green pixel or a blue pixel, and each of the plurality of second pixels comprises one of a red pixel, a green pixel or a blue pixel.

6. The display structure according to claim 2, wherein shapes of the plurality of first openings and the plurality of second openings comprise a polygon shape or circle shape.

7. The display structure according to claim 6, wherein the polygon shape comprises one of a triangle, a quadrangle, and a hexagon.

8. The display structure according to claim 1, wherein an area of the first region is greater than that of the second region.

9. The display structure according to claim 1, wherein a middle region of an edge portion on a side of the first region is provided with a notch, and the second region is located in the notch.

10. A manufacturing method of a display structure, comprising:
providing a substrate divided into a first region and a second region;
forming a pixel defining layer on the substrate, forming a plurality of first openings in a portion of the pixel defining layer corresponding to the first region, and forming a plurality of second openings in a portion of the pixel defining layer corresponding to the second region, wherein areas of the plurality of first openings are less than areas of the plurality of second openings.

11. The method according to claim 10, wherein before forming the pixel defining layer on the substrate, the method further comprises:
forming a first lower electrode layer in the first region, the first lower electrode layer comprising a plurality of first lower electrodes corresponding to the plurality of first openings which are to be formed;
forming a second lower electrode layer in the second region, the second lower electrode layer comprising a plurality of second lower electrodes corresponding to the plurality of second openings which are to be formed.

12. The method according to claim 11, further comprising:
forming a first light emitting layer on each of the plurality of first lower electrodes and in a corresponding one of the plurality of first openings, and forming a second light emitting layer on each of the plurality of second lower electrodes and in a corresponding one of the plurality of second openings;
forming a upper electrode layer on the first light emitting layer and the second light emitting layer.

13. The method according to claim 12, wherein the first light emitting layer and the second light emitting layer are formed by a mask that has apertures with the same dimension.

14. A display device, comprising:
a display structure, comprising:
a first region, comprising a plurality of first pixels;
a second region, comprising a plurality of second pixels, a resolution of the second region being lower than that of the first region; and
a pixel defining layer, wherein a portion of the pixel defining layer which is corresponding to the first region is provided with a plurality of first openings, and the plurality of first openings are corresponding to the plurality of first pixels; a portion of the pixel defining layer which is corresponding to the second region is provided with a plurality of second openings, and the plurality of second openings are corresponding to the plurality of second pixels; and
a camera element and a sensing element located at a region corresponding to and below the second region, wherein
areas of the plurality of first openings are less than those of the plurality of second openings.

15. The display device according to claim 14, wherein the plurality of first openings have substantially the same areas and shapes, and the plurality of second openings have substantially the same areas and shapes;
outer margins of at least two adjacent first openings of the plurality of first openings are connected to form an imaginary opening that has substantially the same area and shape as each of the plurality of second openings.

16. The display device according to claim 14, wherein the plurality of first pixels are same as the plurality of first openings in number, and positions of the plurality of first pixels are corresponding to positions of the plurality of first openings;
the plurality of second pixels are same as the plurality of second openings in number, and positions of the plurality of second pixels are corresponding to positions of the plurality of second openings;
the first pixels in the imaginary opening have the same color, and are different from ones of the plurality of first pixels which are in another adjacent imaginary opening in color;
adjacent ones of the plurality of second pixels have different colors.

17. The display device according to claim 16, wherein at least three of the plurality of first pixels form a first pixel unit, the at least three first pixels of the first pixel unit have different colors; at least three of the plurality of second pixels form a second pixel unit, the at least three second pixels of the second pixel unit have different colors.

18. The display device according to claim 16, wherein each of the plurality of first pixels comprises one of a red pixel, a green pixel or a blue pixel, and each of the plurality of second pixels comprises one of a red pixel, a green pixel or a blue pixel.

19. The display device according to claim 15, wherein shapes of the plurality of first openings and the plurality of second openings comprise a polygon shape or circle shape.
